(19) United States
(12) Patent Application Publication
(10) Pub. No.: US 2010/0072569 A1
(43) Pub. Date: Mar. 25, 2010

(54) Method of forming an isolation layer, method of manufacturing a semiconductor device using the same, and semiconductor device having an isolation layer

(75) Inventors: Tae-Jong Han, Jeonju-si (KR); Mun-Jun Kim, Suwon -si (KR); Deok-Young Jung, Seoul (KR); Eun-Kyung Baek, Suwon-si (KR); Ju-Seon Goo, Suwon-si (KR)

Correspondence Address: MILLS & ONELLO LLP, ELEVEN BEACON STREET, SUITE 605, BOSTON, MA, 02108, US

(73) Assignee: Samsung Electronics, Co., Ltd., Suwon-si (KR)

(21) Appl. No.: 12/586,686

(22) Filed: Sep. 25, 2009

(30) Foreign Application Priority Data
Sep. 25, 2008 (KR) 10-2008-0094274

(51) Int. Cl. H01L 29/06; H01L 21/762

(52) U.S. Cl. 257/506; 438/424; 257/296; 257/E21.547; 257/E29.02

(57) ABSTRACT

In a method of forming an isolation layer, a plurality of trenches is formed on a substrate. A liner is formed on inner walls of the trenches. The liner is thermally oxidized to fill up some of the trenches. The other trenches are filled up with an insulation material. As a result, the isolation layer is free of voids.

### CROSS-REFERENCE TO RELATED APPLICATIONS

This U.S. nonprovisional patent application claims priority under 35 U.S.C. 119 to Korean Patent Application No. 10-2008-0094274, filed on Sep. 25, 2008 in the Korean Intellectual Property Office, the entire contents of which are incorporated herein by reference.

### BACKGROUND

1. Field

Example embodiments relate to a method of forming an isolation layer, a method of manufacturing a semiconductor device using the same, and a semiconductor device having an isolation layer. More particularly, example embodiments relate to a method of forming an isolation layer having a high aspect ratio, a method of manufacturing a semiconductor device using the same, and a semiconductor device including an isolation layer having a high aspect ratio.

2. Description of the Related Art

An isolation layer in a semiconductor device may be formed by forming a trench on a substrate and filling the trench with an insulation layer. In order to improve refresh characteristics of the semiconductor device, before filling the trench with the insulation layer, a liner may be formed on an inner wall of the trench. However, when the trench has a high aspect ratio, an entrance of the trench may be closed by the liner so that a void or a seam may be formed in the trench. Thus, the insulation layer may not fill the trench sufficiently, so that the isolation layer may not be of good quality. Particularly, in a semiconductor device, a plurality of isolation layers having different aspect ratios may be formed, and when isolation layers are formed, voids or seams may be formed in the isolation layers having high aspect ratios, which results in these isolation layers having poor electrical characteristics.

### SUMMARY

Example embodiments provide a method of forming an isolation layer having no voids.

Example embodiments provide a method of manufacturing a semiconductor device using the method of forming the isolation layer having no voids.

Example embodiments provide a semiconductor device including an isolation layer having no voids.

According to one aspect, the present inventive concept is directed to a method of forming an isolation layer. In the method, a plurality of trenches is formed on a substrate. A liner is formed on inner walls of the trenches. The liner is thermally oxidized to fill up some of the trenches. The other trenches are filled up with an insulation material.

In an example embodiment, the liner may be formed using a nitride.

In an example embodiment, the insulation material may include spin on glass (SOG), hydrogen silsesquioxane (HSQ) or flowable oxide (FOX).

In an example embodiment, prior to forming the liner, a pad oxide layer may be further formed on the inner walls of the trenches.

In an example embodiment, when the liner is formed on the inner walls of the trenches, a wet etch process or a dry etch process may be performed to open entrances of the trenches when the entrances of the trenches are closed.

In an example embodiment, the trenches may have aspect ratios different from each other.

According to another aspect, the present inventive concept is directed to a method of manufacturing a semiconductor device. In the method, a plurality of trenches having aspect ratios different from each other is formed on a substrate including a cell region and a peripheral region. A liner is formed on inner walls of the trenches. The liner is thermally oxidized to fill up some of the trenches having relatively high aspect ratios to form a first isolation layer. The other trenches having relatively low aspect ratios are filled up with an insulation material to form a second isolation layer. A gate structure is formed on the substrate having the first and second isolation layers thereon. An impurity region is formed at an upper portion of the substrate. A capacitor is formed to be electrically connected to the impurity region.

In an example embodiment, the trenches having the high aspect ratios may be formed in the cell region.

According to another aspect, the present inventive concept is directed to a semiconductor device. The semiconductor device includes a first isolation layer, a second isolation layer, a gate structure, an impurity region and a capacitor. The first isolation layer includes a nitride liner and an oxynitride layer sequentially stacked on a substrate which includes a cell region and a peripheral region. The second isolation layer includes the nitride liner, the oxynitride layer and an SOG layer sequentially stacked on the substrate. The gate structure is formed on the substrate having the first and second isolation layers thereon. The impurity region is formed at an upper portion of the substrate. The capacitor is electrically connected to the impurity region.

In an example embodiment, the first isolation layer may be formed in the cell region.

According to example embodiments, isolation layers having high aspect ratios or having different aspect ratios may be free of voids so that a semiconductor device having the isolation layers may have good refresh characteristics.

### BRIEF DESCRIPTION OF THE DRAWINGS

The foregoing and other features and advantages of the inventive concept will be apparent from the more particular description of preferred embodiments of the inventive concept, as illustrated in the accompanying drawings in which like reference characters refer to the same parts throughout the different views. The drawings are not necessarily to scale, emphasis instead being placed upon illustrating the principles of the inventive concept. In the drawings, the thickness of layers and regions are exaggerated for clarity.

FIGS. 1 to 6 are cross-sectional views illustrating a method of forming an isolation layer in accordance with some example embodiments.

FIGS. 7 to 12 are cross-sectional views illustrating a method of forming an isolation layer in accordance with other example embodiments.

FIGS. 13 to 24 are cross-sectional views illustrating a method of manufacturing a semiconductor device in accordance with example embodiments.

FIG. 25 is a block diagram illustrating a system having a dynamic random access memory (DRAM) device including an isolation layer in accordance with some example embodiments.

FIG. 26 is a block diagram illustrating a system having a DRAM device including an isolation layer in accordance with other example embodiments.

### DETAILED DESCRIPTION OF THE EMBODIMENTS

This application claims priority under 35 U.S.C. §119 to Korean Patent Application No. 10-2008-0094274, filed on Sep. 25, 2008, in the Korean Intellectual Property Office (KIPO), the contents of which are herein incorporated by reference in their entirety.

Various example embodiments will be described more fully hereinafter with reference to the accompanying drawings, in which some example embodiments are shown. The present inventive concept may, however, be embodied in many different forms and should not be construed as limited to the example embodiments set forth herein. Rather, these example embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be described in detail with reference to the accompanying drawings.

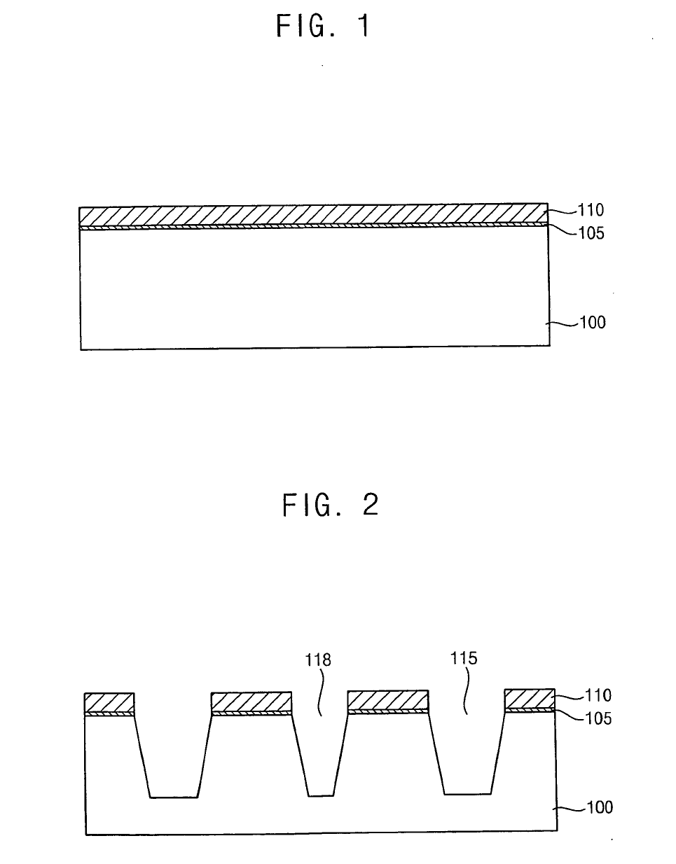

FIGS. 1 to 6 are cross-sectional views illustrating a method of forming an isolation layer in accordance with some example embodiments.

Referring to FIG. 1, a pad oxide layer 105 may be formed on a substrate 100. The pad oxide layer 105 may be formed by a thermal oxidation process. The pad oxide layer 105 may be formed to a thickness of about 50 Å to about 150 Å.

A hard mask 110 may be formed on the pad oxide layer 105. The hard mask 110 may be formed using a material having an etch ratio different from those of the substrate 100 and the pad oxide layer 105. In an example embodiment, the hard mask 110 may be formed using silicon nitride.

Referring to FIG. 2, after patterning the hard mask 110, first and second trenches 115 and 118 may be formed on the substrate 100 using the patterned hard mask 110. The first and second trenches 115 and 118 may have different aspect ratios.

In an example embodiment, the first trench 115 may have an aspect ratio lower than that of the second trench 118. The first trench 115 may be formed at an isolation region having a relatively large gap between active regions, and the second trench 118 may be formed at an isolation region having a relatively small gap between active regions.

The hard mask 110 may be a single layer or a multi-layer. In an example embodiment, the hard mask 110 may be a multi-layer having a lower layer including an oxide or a nitride, an intermediate layer including an organic material, and an upper layer including a nitride.

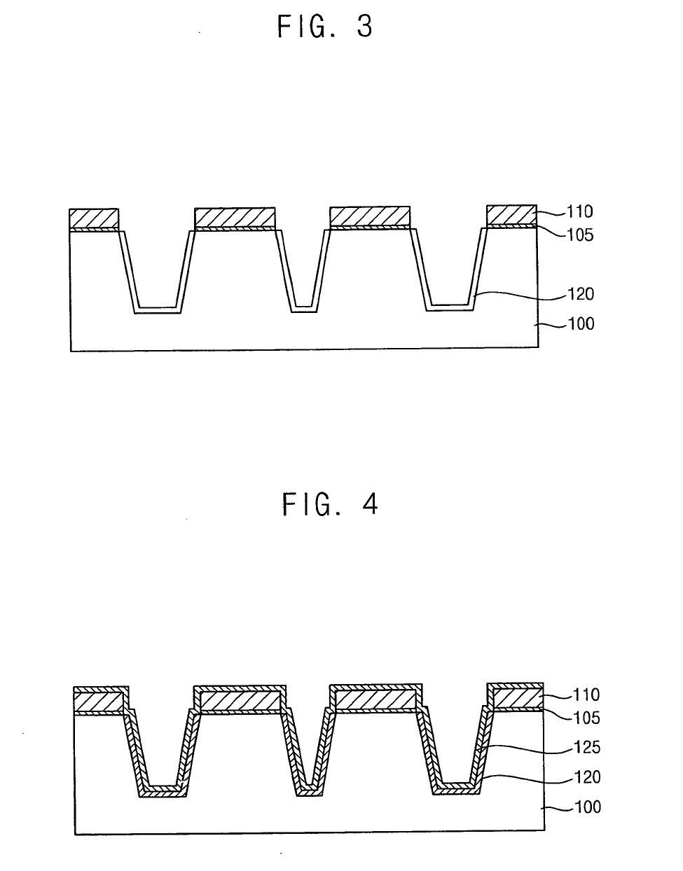

Referring to FIG. 3, a thermal oxide layer 120 may be formed on inner walls of the first and second trenches 115 and 118. The thermal oxide layer 120 may be formed by a radical oxidation process using a furnace, or a rapid thermal annealing (RTA) process. The thermal oxide layer 120 may be formed to a thickness of about 50 Å to about 200 Å.

Referring to FIG. 4, a liner 125 may be formed on the thermal oxide layer 120, the pad oxide layer 105 and the hard mask 110. In an example embodiment, the liner 125 may be formed using a nitride. The liner 125 may be formed by a low pressure chemical vapor deposition (LPCVD) process.

The liner 125 may be formed to a thickness at which an entrance of the second trench 118 having the relatively high aspect ratio may not be closed. In an example embodiment, the liner 125 may be formed to a thickness of about 100 Å to about 200 Å.

When the entrance of the second trench 118 is closed in the formation of the liner 125 so that a void or a seam is generated in the second trench 118, a wet etch or a dry etch process may be further performed so that a portion of the liner 125 at the entrance of the second trench 118 may be removed. Accordingly, the entrance of the second trench 118 may be opened.

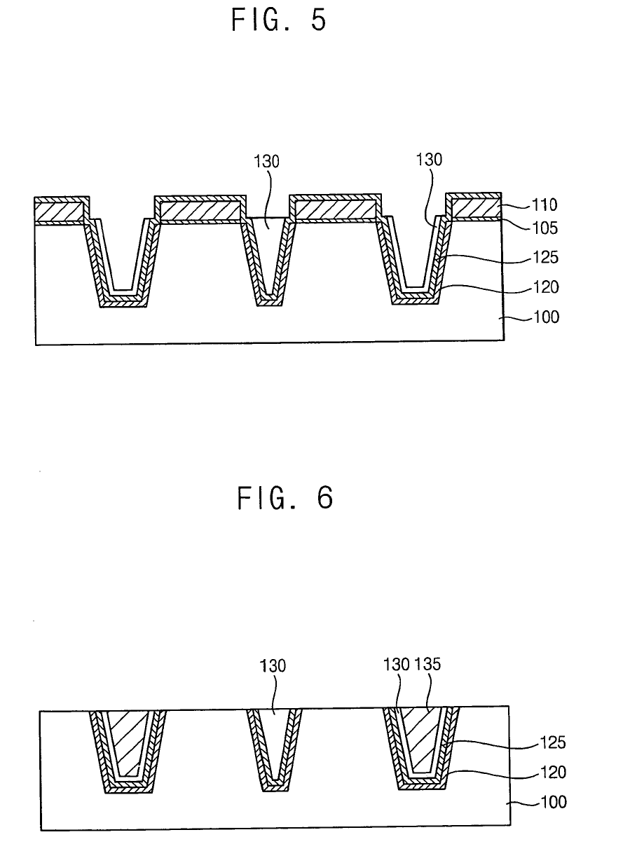

Referring to FIG. 5, a thermal oxidation process may be performed on the liner 125, thereby forming an oxynitride layer 130 on the liner 125. The thermal oxidation process may be performed at a temperature of about 600° C. to about 800° C. using a furnace, or by a RTA process under an atmosphere of oxygen gas.

When the thermal oxidation process is performed, the remaining portion of the second trench 118 having the high aspect ratio may be filled up with the oxynitride layer 130. In an example, a nitride layer having a thickness of about 110 Å was thermally oxidized, so that an oxynitride layer having a thickness of about 100 Å was formed and a nitride layer having a thickness of about 30 Å remained beneath the oxynitride layer.

After performing the thermal oxidation process, the second trench 118 having the high aspect ratio may be filled up with the oxynitride layer 130, the liner 125 and the thermal oxide layer 120, and the first trench 115 having the low aspect ratio may have remaining space portion which may be filled with another material.

Referring to FIG. 6, an insulation layer 135 may be filled into the remaining space portion of the first trench 115. The insulation layer 135 may be formed using a spin on glass (SOG) such as tonen silazene (TOSZ), hydrogen silsesquioxane (HSQ), flowable oxide (FOX), etc.

In an example embodiment, the remaining portion of the first trench 115 may be filled up by a high-density plasma (HDP) process. In another example embodiment, the first trench 115 may be filled up with a double-layer or by a deposition-etch-deposition-etch-deposition (DEDED) process.

The insulation layer 135, the oxynitride layer 130, the liner 125, the hard mask 110 and the pad oxide layer 105 may be planarized to form a first isolation layer in the first trench 115 and a second isolation layer in the second trench 118. The first isolation layer may include the thermal oxide layer 120, the liner 125, the oxynitride layer 130 and the insulation layer 135. The second isolation layer may include the thermal oxide layer 120, the liner 125 and the oxynitride layer 130.

The first and second isolation layers may not have voids or seams, so that a semiconductor device including the isolation layers may have good refresh characteristics.

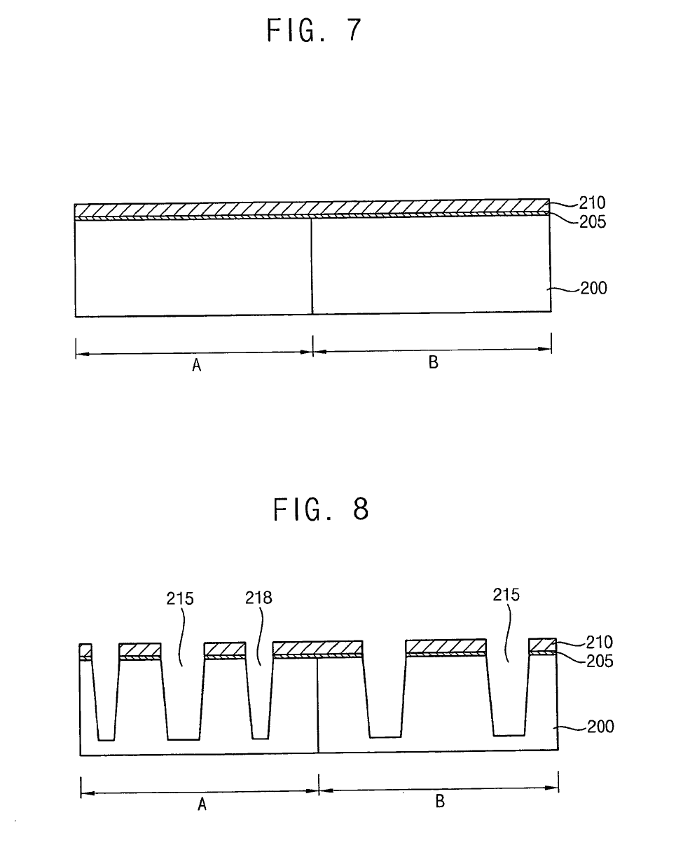

FIGS. 7 to 12 are cross-sectional views illustrating a method of forming an isolation layer in accordance with other example embodiments.

Referring to FIG. 7, a pad oxide layer 205 may be formed on a substrate 200. The pad oxide layer 205 may be formed by a thermal oxidation process. The pad oxide layer 205 may be formed to a thickness of about 50 Å to about 150 Å.

The substrate 200 may include a cell region A and a peripheral region B.

A hard mask 210 may be formed on the pad oxide layer 205. The hard mask 210 may be formed using a material having an etch ratio different from those of the substrate 200 and the pad oxide layer 205. In an example embodiment, the hard mask 210 may be formed using silicon nitride.

Referring to FIG. 8, after patterning the hard mask 210, first and second trenches 215 and 218 may be formed on the substrate 200 using the patterned hard mask 210. The first and second trenches 215 and 218 may have different aspect ratios. For example, the first trench 215 may have an aspect ratio lower than that of the second trench 218.

In an example embodiment, the first trench 215 may be formed in both of the cell and peripheral regions A and B, and the second trench 218 may be formed in the cell region A.

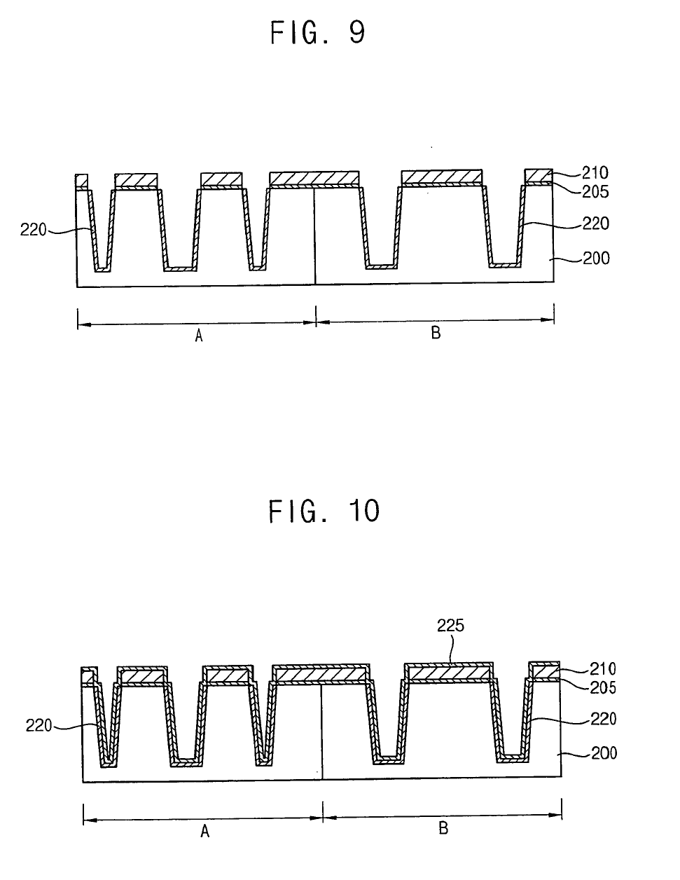

Referring to FIG. 9, a thermal oxide layer 220 may be formed on inner walls of the first and second trenches 215 and 218. The thermal oxide layer 220 may be formed by a radical oxidation process using a furnace, or a RTA process. The thermal oxide layer 220 may be formed to a thickness of about 50 Å to about 200 Å.

Referring to FIG. 10, a liner 225 may be formed on the thermal oxide layer 220, the pad oxide layer 205 and the hard mask 210. In an example embodiment, the liner 225 may be formed using a nitride. The liner 225 may be formed by a LPCVD process.

The liner 225 may be formed to a thickness at which an entrance of the second trench 218 having the relatively high aspect ratio may not be closed. In an example embodiment, the liner 225 may be formed to a thickness of about 100 Å to about 200 Å.

When the entrance of the second trench 218 is closed in the formation of the liner 225 so that a void or a seam is generated in the second trench 218, a wet etch or a dry etch process may be further performed so that a portion of the liner 225 at the entrance of the second trench 218 may be removed. Accordingly, the entrance of the second trench 218 may be opened.

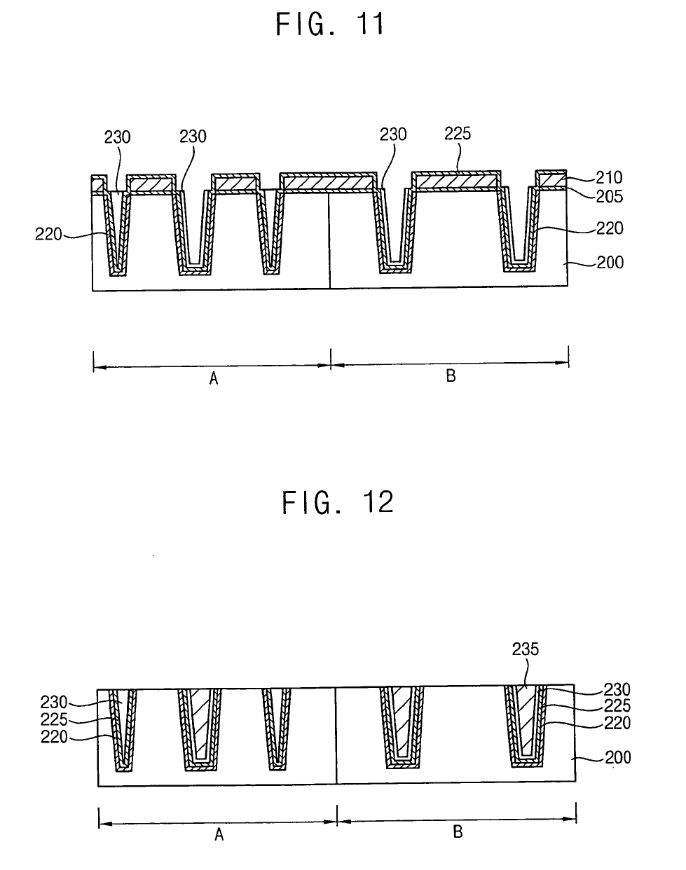

Referring to FIG. 11, a thermal oxidation process may be performed on the liner 225, thereby forming an oxynitride layer 230 on the liner 225. The thermal oxidation process may be performed at a temperature of about 600° C. to about 800° C. using a furnace, or by a RTA process under an atmosphere of oxygen gas.

When the thermal oxidation process is performed, the remaining portion of the second trench 218 having the high aspect ratio may be filled up with the oxynitride layer 230. In an example, a nitride layer having a thickness of about 110 Å was thermally oxidized, so that an oxynitride layer having a thickness of about 100 Å was formed and a nitride layer having a thickness of about 30 Å remained beneath the oxynitride layer.

After performing the thermal oxidation process, the second trench 218 having the high aspect ratio may be filled up with the oxynitride layer 230, the liner 225 and the thermal oxide layer 220, and the first trench 215 having the low aspect ratio may have a remaining space portion that may be filled up with another material.

Referring to FIG. 12, an insulation layer 235 may be filled into the remaining space portion of the first trench 215. The insulation layer 235 may be formed using a SOG such as TOSZ, HSQ, FOX, etc.

In an example embodiment, the remaining space portion of the first trench 215 may be filled up by a HDP process. In another example embodiment, the first trench 215 may be filled up with a double-layer or by a DEDED process.

The insulation layer 235, the oxynitride layer 230, the liner 225, the hard mask 210 and the pad oxide layer 205 may be planarized to form a first isolation layer in the first trench 215 and a second isolation layer in the second trench 218. The first isolation layer may include the thermal oxide layer 220, the liner 225, the oxynitride layer 230 and the insulation layer 235. The second isolation layer may include the thermal oxide layer 220, the liner 225 and the oxynitride layer 230.

The first and second isolation layers may not have voids or seams, so that a semiconductor device including the isolation layers may have good refresh characteristics.

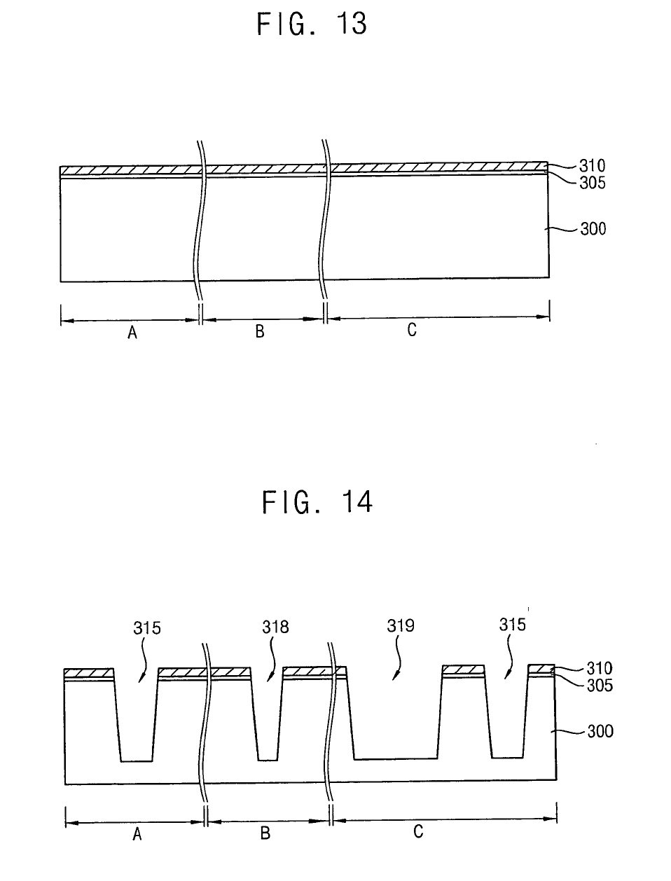

FIGS. 13 to 24 are cross-sectional views illustrating a method of manufacturing a semiconductor device in accordance with example embodiments. In the figures, regions A and B are cross-sectional views of a cell region of the semiconductor device cut along a first direction and a second direction substantially perpendicular to the first direction, respectively, and a region C is a cross-sectional view of a peripheral region of the semiconductor device.

Referring to FIG. 13, a pad oxide layer 305 may be formed on a substrate 300. The pad oxide layer 305 may be formed by a thermal oxidation process. The pad oxide layer 305 may be formed to a thickness of about 50 Å to about 150 Å.

A hard mask 310 may be formed on the pad oxide layer 305. The hard mask 310 may be formed using a material having an etch ratio different from those of the substrate 300 and the pad oxide layer 305. For example, the hard mask 310 may be formed using silicon nitride. In some example embodiments, the hard mask 310 may be formed to have a multi-layered structure, which has a lower layer including a nitride, an intermediate layer including an organic material, and an upper layer including a nitride. The lower layer may be formed to a thickness of about 2,000 Å to about 3,000 Å by a CVD process, the intermediate layer, e.g., an amorphous carbon layer (ACL) may be formed to a thickness of about 2,000 Å to about 3,000 Å, and the upper layer, e.g., an anti-reflection layer (ARL) may be formed to a thickness of about 500 Å.

Referring to FIG. 14, after patterning the hard mask 310, first, second and third trenches 315, 318 and 319 may be formed on the substrate 300 using the patterned hard mask 310. The first, second and third trenches 315, 318 and 319 may have different aspect ratios. For example, the first trench 315 may have an aspect ratio lower than that of the second trench 318, and the third trench 319 may have an aspect ratio lower than that of the first trench 315.

In some example embodiments, the first trench 315 may be formed in the regions A and C, the second trench 318 may be formed in the region B, and the third trench 319 may be formed in the region C. Specifically, the first trench 315 of the region A may be formed between adjacent active regions in the first direction, and the second trench 318 may be formed between adjacent active regions in the second direction, which are less distant from each other than those in the first direction.

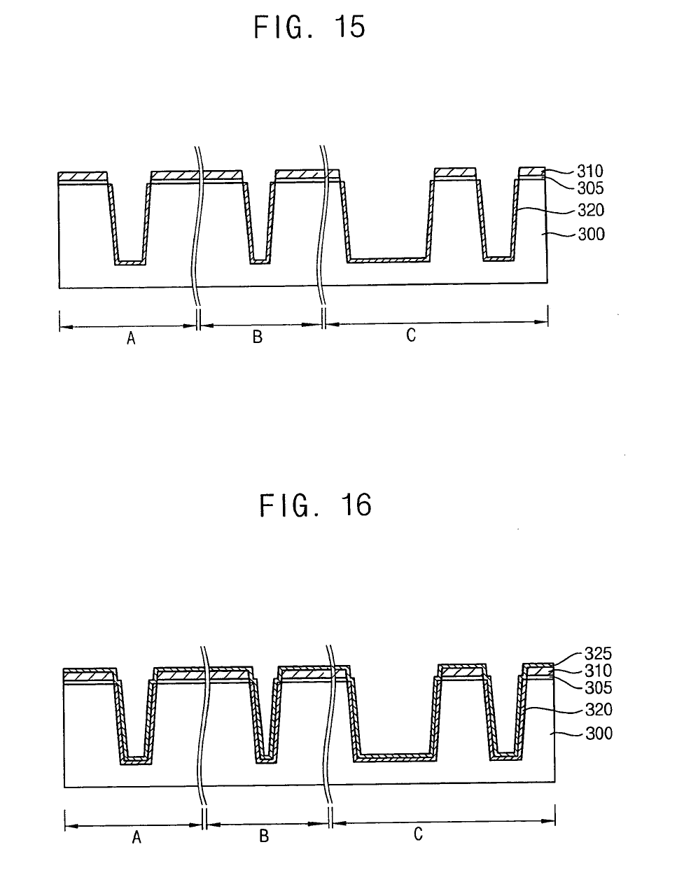

Referring to FIG. 15, a thermal oxide layer 320 may be formed on inner walls of the first, second and third trenches 315, 318 and 319. The thermal oxide layer 320 may be formed by a radical oxidation process using a furnace, or a RTA process. The thermal oxide layer 320 may be formed to a thickness of about 50 Å to about 200 Å.

Referring to FIG. 16, a liner 325 may be formed on the thermal oxide layer 320, the pad oxide layer 305 and the hard mask 310. In an example embodiment, the liner 325 may be formed using a nitride. The liner 325 may be formed by a LPCVD process.

The liner 325 may be formed to a thickness at which an entrance of the second trench 318 having the highest aspect ratio may not be closed. In an example embodiment, the liner 325 may be formed to a thickness of about 100 Å to about 200 Å.

When the entrance of the second trench 318 is closed in the formation of the liner 325 so that a void or a seam is generated in the second trench 318, a wet etch or a dry etch process may be further performed so that a portion of the liner 325 at the entrance of the second trench 318 may be removed. Accordingly, the entrance of the second trench 318 may be opened.

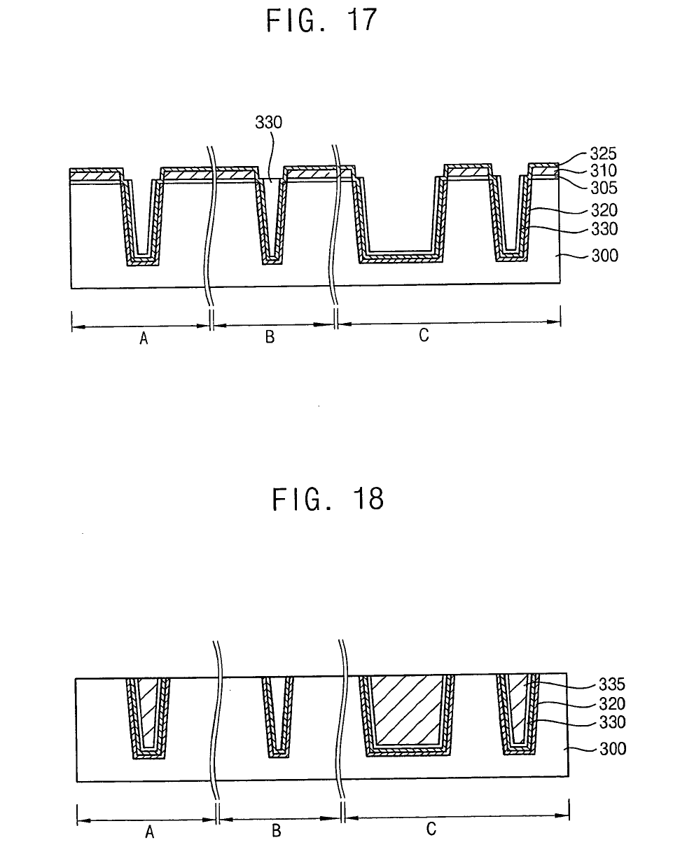

Referring to FIG. 17, a thermal oxidation process may be performed on the liner 325, thereby forming an oxynitride layer 330 on the liner 325. The thermal oxidation process may be performed at a temperature of about 600° C. to about 800° C. using a furnace, or by a RTA process under an atmosphere of oxygen gas.

When the thermal oxidation process is performed, the remaining portion of the second trench 318 having the high aspect ratio may be filled up with the oxynitride layer 330. In an example, a nitride layer having a thickness of about 110 Å was thermally oxidized, so that an oxynitride layer having a thickness of about 100 Å was formed and a nitride layer having a thickness of about 30 Å remained beneath the oxynitride layer.

After performing the thermal oxidation process, the second trench 318 having the high aspect ratio may be filled up with the oxynitride layer 330, the liner 325 and the thermal oxide layer 320, and the first and third trenches 315 and 319 having the relatively low aspect ratios may have remaining space portions that may be filled up with another material.

Referring to FIG. 18, an insulation layer 335 may be filled into the remaining space portions of the first and third trenches 315 and 319. The insulation layer 335 may be formed using a SOG such as TOSZ, HSQ, FOX, etc.

In an example embodiment, the remaining portions of the first and third trenches 315 and 319 may be filled up by a HDP process. In another example embodiment, the first and third trenches 315 and 319 may be filled up with a double-layer or by a DEDED process.

The insulation layer 335, the oxynitride layer 330, the liner 325, the hard mask 310 and the pad oxide layer 305 may be planarized to form first, second and third isolation layers in the first, second and third trenches 315, 318 and 319, respectively. The first and third isolation layers may include the thermal oxide layer 320, the liner 325, the oxynitride layer 330 and the insulation layer 335. The second isolation layer may include the thermal oxide layer 320, the liner 325 and the oxynitride layer 330.

The first, second and third isolation layers may be free of voids or seams, even though the isolation layers have different aspect ratios.

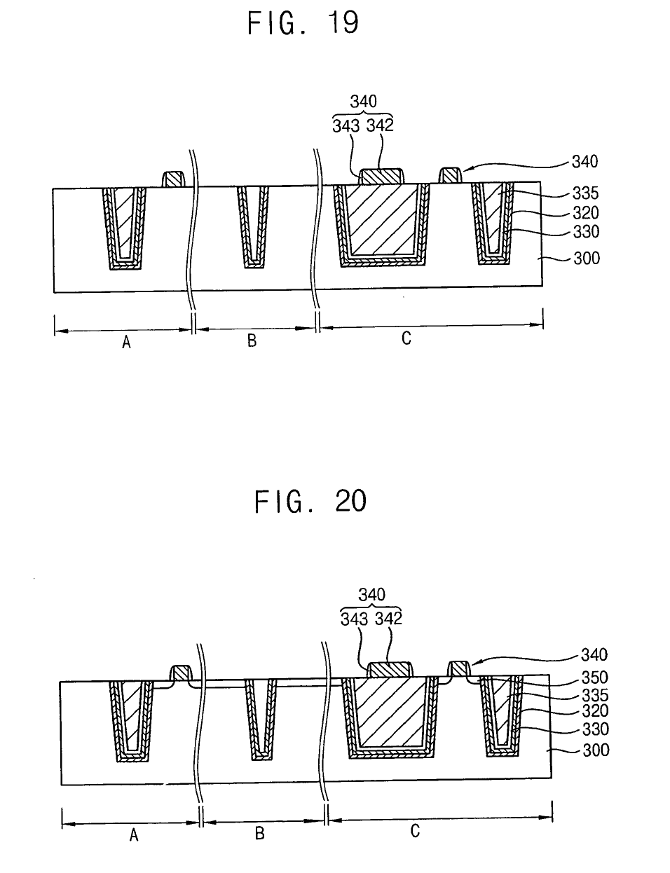

Referring to FIG. 19, gate structures 340 including gate electrodes 342 and gate spacers 343 may be formed on the substrate 300 having the isolation layers thereon. Each of the gate electrodes 340 may include a metal silicide, and a hard mask (not shown) may be further formed on the metal silicide layer.

Gate insulation layers (not shown) may be further formed between the substrate 300 and the gate electrodes 342. The gate insulation layers may be formed using silicon oxide, hafnium oxide, tantalum oxide, etc. Alternatively, the gate insulation layers may be formed to have a multi-layered structure including, e.g., an oxide layer, a nitride layer and an oxide layer sequentially stacked.

The gate structures 340 in the cell region A and the peripheral region C may not be formed simultaneously, and may have different structures.

Referring to FIG. 20, impurity regions 350 may be formed at upper portions of the substrate 300. The impurity regions 350 may serve as source/drain regions of transistors.

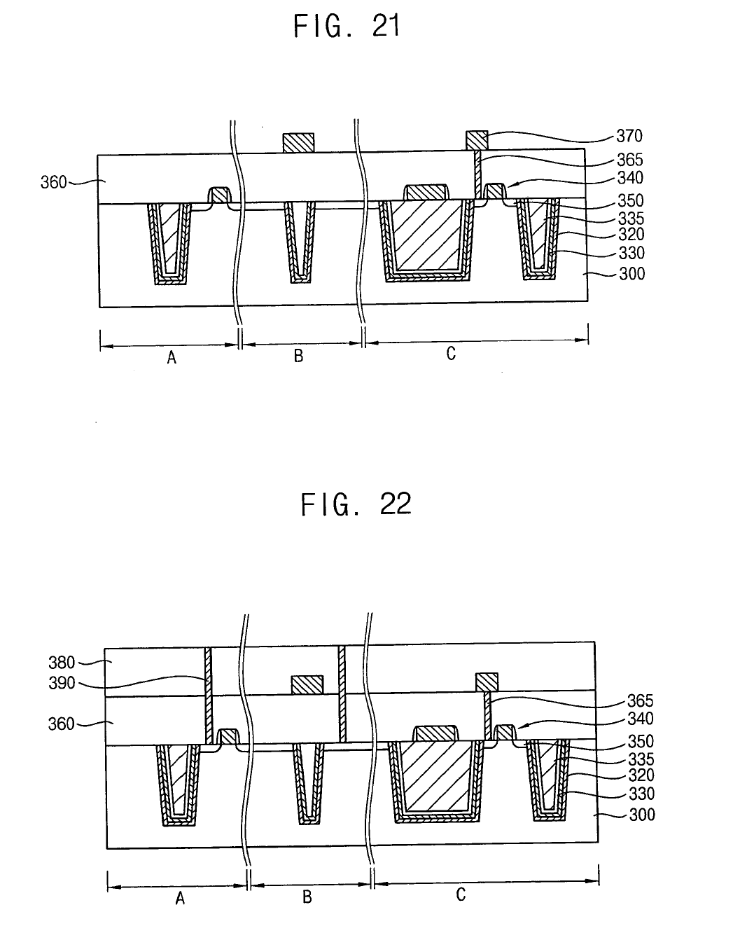

Referring to FIG. 21, a first insulating interlayer 360 may be formed on the substrate 300 to cover the gate structures 340, the isolation layers and the impurity regions 350. The first insulating interlayer 360 may be formed by a CVD process or a HDP process using boron phosphosilicate glass (BPSG), phosphosilicate glass (PSG), plasma enhanced tetraethyl-orthosilicate (PE-TEOS) or HDP oxide.

The first insulating interlayer 360 may be partially removed to form a first contact hole (not shown) exposing the impurity regions 350. A bitline plug 365 may be formed in the first contact hole. The bitline plug 365 may be formed using doped polysilicon, a metal or a conductive metal nitride, etc.

A bitline 370 may be formed on the first insulating interlayer 360 to be electrically connected to the bitline plug 365.

Referring to FIG. 22, a second insulating interlayer 380 may be formed on the first insulating interlayer 360 and the bitline 370. The second insulating interlayer 380 may be formed using BPSG, PSG PE-TEOS or HDP oxide.

The first and second insulating interlayers 360 and 380 may be partially removed to form a second contact hole (not shown) exposing the impurity regions 350. A capacitor plug 390 may be formed in the second contact hole. The capacitor plug 390 may be formed using doped polysilicon, a metal or a conductive metal nitride, etc.

Referring to FIG. 23, a lower electrode 400 may be formed on the second insulating interlayer 380 to be electrically connected to the capacitor plug 390. A dielectric layer 410 and an upper electrode 420 may be sequentially formed on the lower electrode 400 and the second insulating interlayer 380. The lower and upper electrodes 400 and 420 may be formed using titanium, tantalum, titanium nitride, tantalum nitride, platinum, etc. The dielectric layer 410 may be formed using zirconium oxide, zirconium oxynitride, etc.

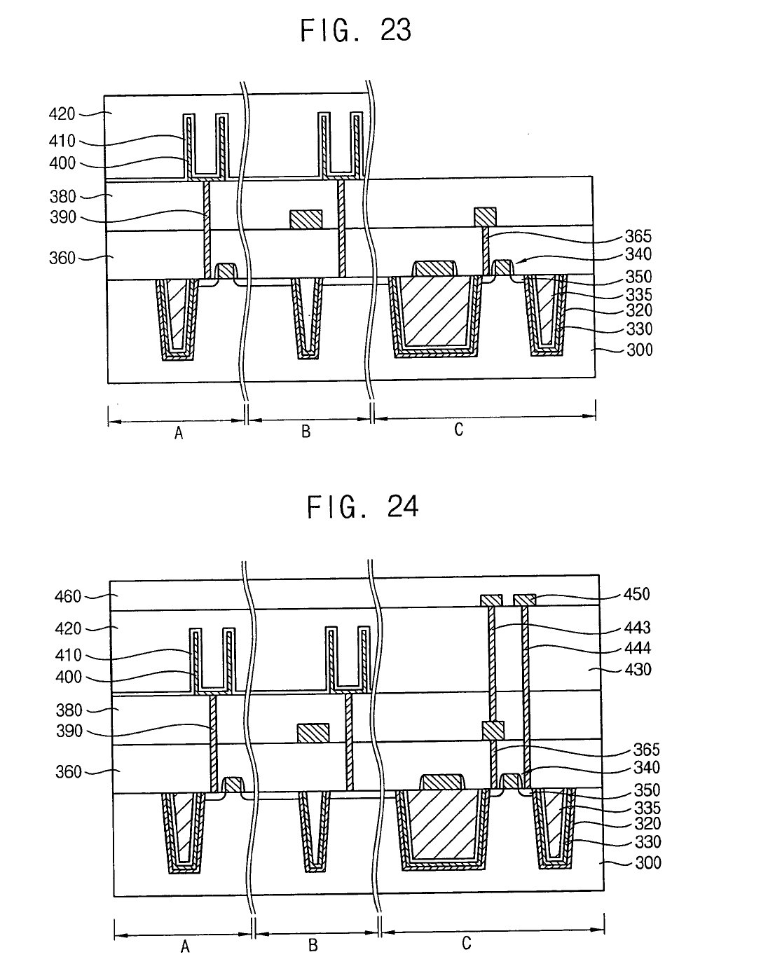

Referring to FIG. 24, a third insulating interlayer 430 may be formed on the second insulating interlayer 380 and the upper electrode 420. The third insulating interlayer 430 may be formed using TEOS, HDP oxide, etc. The third insulating interlayer 430 may compensate the height difference between the cell region A and B and the peripheral region C. The third insulating interlayer 430 may be planarized by a self-stopping chemical mechanical polishing (CMP) process and/or an etch back process.

Plugs 443 and 444 may be formed through the first, second and/or third insulating interlayers 360, 380 and/or 430. Metal wirings 450 may be formed on the third insulating interlayer 430 to be electrically connected to the plug 443 or the plug 444. A protection layer 460 may be formed on the third insulating interlayer 420 to cover the metal wirings 450.

Thus, the semiconductor device including the isolation layers may have good refresh characteristics because the isolation layers have no voids or seams therein.

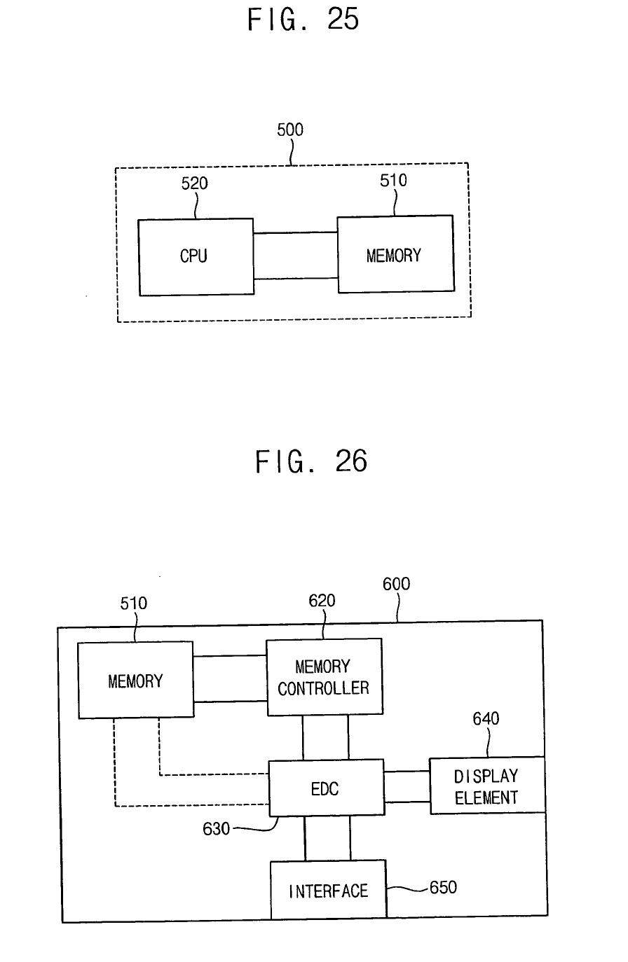

FIG. 25 is a block diagram illustrating a system having a dynamic random access memory (DRAM) device including an isolation layer in accordance with example embodiments.

Referring to FIG. 25, a system 500 may include a computer system. The system 500 may have a central processing unit (CPU) 520 and a memory 510. The memory may be a DRAM device including a plurality of isolation layers, which may have different aspect ratios in a cell region and a peripheral region. Each of the isolation layers may be formed to have a liner and/or an insulation layer.

The system 500 may include desktop computers or laptop computers. The system 500 may also include digital products having the memory 510 storing data. The memory 510 may be connected to the CPU 520 directly or through a BUS.

FIG. 26 is a block diagram illustrating a system having a DRAM device including an isolation layer in accordance with example embodiments.

Referring to FIG. 26, a system 600 may be a portable device. The portable device 600 may include memory 510 in the form of a DRAM device having an isolation layer therein. Examples of the portable device 600 may include an MP3 player, a video player, a portable multi-media player (PMP), etc.

The portable device 600 may include the memory 510, the memory controller 620, an encoder/decoder (EDC) 630, a display element 640 and an interface 650. Data may be input to or output from the memory 510 by way of the memory controller 620. As illustrated with the dashed lines of FIG. 26, data may be directly input from the EDC 630 to the memory 510, or data may be directly output from the memory 510 to the EDC 630.

The EDC 630 may encode data to be stored in the memory 510. For example, the EDC 630 may execute encoding for storing audio data and/or video data in the memory 510 of an MP3 player or a PMP player. Further, the EDC 630 may execute MPEG encoding for storing video data in the memory 510. Moreover, the EDC 630 may include multiple encoders to encode different types of data depending on their formats. For example, the EDC 630 may include an MP3 encoder for encoding audio data and an MPEG encoder for encoding video data.

The EDC 630 may also decode data that is output from the memory 510. For example, the EDC 630 may execute MP3 decoding to decode audio data from the memory 510. Further, the EDC 630 may execute MPEG decoding to decode video data from the memory 510. Moreover, the EDC 630 may include multiple decoders to decode different types of data depending on their formats. For example, the EDC 630 may include an MP3 decoder for audio data and an MPEG decoder for video data.

In other embodiments, the EDC 630 may include only a decoder. For example, encoded data may be input to the EDC 630, and then the EDC 630 may decode the input data for transfer into the memory controller 620 or the memory 510.

The EDC 630 may receive data to be encoded or data being encoded by way of the interface 650. The interface 650 may comply with established standards (e.g., FireWire, USB, etc.); accordingly, the interface 650 may include a FireWire interface, a USB interface, etc., and data may be output from the memory 510 by way of the interface 650.

The display element 640 may display a representation of user data that is output from the memory 510 and decoded by the EDC 630. Examples of the display element 640 may include a speaker outputting an audio representation of the data, a display screen outputting a video representation of the data, etc.

According to example embodiments, isolation layers having high aspect ratios or having different aspect ratios may have no voids therein so that a semiconductor device having the isolation layers may have good refresh characteristics.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A method of forming an isolation layer, comprising:
forming a plurality of trenches on a substrate, the trenches having aspect ratios different from each other;
forming a liner on inner walls of the trenches;
thermally oxidizing the liner to fill up some of the trenches having relatively high aspect ratios; and
filling up the other trenches having relatively low aspect ratios with an insulation material.

2. The method of claim 1, wherein the insulation material comprises any one selected from the group consisting of spin on glass (SOG), hydrogen silsesquioxane (HSQ) and flowable oxide (FOX).

3. The method of claim 1, wherein the insulation material includes tonen silazene (TOSZ).

4. The method of claim 1, prior to forming the liner, further comprising forming a pad oxide layer on the inner walls of the trenches.

5. The method of claim 1, wherein forming the liner on the inner walls of the trenches includes performing a wet etch process or a dry etch process to open entrances of the trenches when the entrances of the trenches are closed.

6. The method of claim 1, wherein thermally oxidizing the liner includes performing a rapid thermal annealing (RTA) process under an atmosphere of oxygen gas.

7. The method of claim 1, wherein the liner includes silicon nitride.

8. A method of manufacturing a semiconductor device, comprising:
forming a plurality of trenches on a substrate including a cell region and a peripheral region, the trenches having aspect ratios different from each other;
forming a liner on inner walls of the trenches;
thermally oxidizing the liner to fill up some of the trenches having relatively high aspect ratios to form a first isolation layer;
filling up the other trenches having relatively low aspect ratios with an insulation material to form a second isolation layer;
forming a gate structure on the substrate having the first and second isolation layers thereon;
forming an impurity region at an upper portion of the substrate; and
forming a capacitor to be electrically connected to the impurity region.

9. The method of claim 8, wherein the insulation material comprises any one selected from the group consisting of SOG, HSQ and FOX.

10. The method of claim 8, wherein the insulation material includes TOSZ.

11. The method of claim 8, prior to forming the liner, further comprising forming a pad oxide layer on the inner walls of the trenches.

12. The method of claim 8, wherein forming the liner on the inner walls of the trenches includes performing a wet etch process or a dry etch process to open entrances of the trenches when the entrances of the trenches are closed.

13. The method of claim 8, wherein thermally oxidizing the liner includes performing an RTA process under an atmosphere of oxygen gas.

14. The method of claim 8, wherein the liner includes silicon nitride.

15. The method of claim 8, wherein the trenches having the high aspect ratios are formed in the cell region.

16. A semiconductor device comprising:
a first isolation layer including a nitride liner and an oxynitride layer sequentially stacked on a substrate, the substrate including a cell region and a peripheral region;
a second isolation layer including the nitride liner, the oxynitride layer and an SOG layer sequentially stacked on the substrate;
a gate structure on the substrate having the first and second isolation layers thereon;
an impurity region at an upper portion of the substrate; and
a capacitor electrically connected to the impurity region.

17. The semiconductor device of claim 16, wherein the first isolation layer is formed in the cell region.

18. The semiconductor device of claim 16, wherein the SOG layer includes TOSZ.

19. The semiconductor device of claim 16, further comprising a pad oxide layer between the substrate and the first and second isolation layers.

20. The semiconductor device of claim 16, wherein the nitride liner includes silicon nitride.
